(19) United States
(12) Patent Application Publication
(10) Pub. No.: US 2020/0010948 A1
(43) Pub. Date: Jan. 9, 2020

(54) SHIELDED SPUTTER DEPOSITION APPARATUS AND METHOD

(71) Applicant: BEIJING APOLLO DING RONG SOLAR TECHNOLOGY CO., LTD., Beijing (CN)

(72) Inventors: Timothy NAGLE, Campbell, CA (US); Thomas HECKEL, Mountain View, CA (US)

(21) Appl. No.: 16/028,165

(22) Filed: Jul. 5, 2018

(51) Int. Cl. C23C 14/34; C23C 14/06; H01J 37/34; H01L 31/18; H01L 31/0224; H01L 31/05; H01L 31/0392; H01L 21/02

(52) U.S. Cl. CPC C23C 14/3407; C23C 14/0623; H01J 37/3423; H01L 31/18; H01L 21/02631; H01L 31/0508; H01L 31/03928; H01L 21/02425; H01L 21/02568; H01L 31/022425

(57) ABSTRACT

A shielded sputter deposition system and method, the system including a process module including: a vacuum enclosure configured to receive a moving substrate, sputtering targets disposed in the vacuum enclosure, each sputtering target including a target material, and a peripheral shield disposed between the and substrate and an interstitial space located between adjacent sputtering targets. The peripheral shield may be configured to at least partially block indirect deposition of sputtered target material onto the substrate and to permit direct deposition of the sputtered target material onto the substrate.

### BACKGROUND

The present disclosure is directed generally to a shielded sputter deposition apparatus and method for deposition of a sputtered conductive material.

A “thin-film” photovoltaic material refers to a polycrystalline or amorphous photovoltaic material that is deposited as a layer on a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (“CIGS”).

Thin-film photovoltaic cells (also known as photovoltaic cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

### SUMMARY

According to various embodiments, provided is a sputter deposition system comprising a process module including: a vacuum enclosure configured to receive a moving substrate; sputtering targets disposed in the vacuum enclosure, each sputtering target including a target material; and a peripheral shield disposed between the and substrate and an interstitial space located between adjacent sputtering targets, the peripheral shield configured to at least partially block indirect deposition of the sputtered target material onto the substrate and to permit direct deposition of the sputtered target material onto the substrate.

According to various embodiments, provided is a sputter deposition method comprising: sputtering a target material using sputtering targets disposed in a vacuum enclosure; and depositing the sputtered target material onto a substrate moving through the vacuum enclosure, via direct deposition, while at least partially blocking indirect deposition of the sputtered target material onto the substrate using a peripheral shield disposed between the substrate and an interstitial space located between adjacent sputtering targets.

### BRIEF DESCRIPTION OF THE DRAWINGS

FIG. 1 is a schematic vertical cross sectional view of a thin-film photovoltaic cell according to an embodiment of the present disclosure.

FIG. 2 is a schematic top view diagram of a first exemplary modular deposition apparatus that can be used to manufacture the photovoltaic cell illustrated in FIG. 1 according to an embodiment of the present disclosure.

FIG. 3 is a schematic top view diagram of a second exemplary modular deposition apparatus that can be used to manufacture the photovoltaic cell illustrated in FIG. 1 according to an embodiment of the present disclosure.

FIG. 4 is a schematic top view diagram of an exemplary sealing connection unit according to an embodiment of the present disclosure.

FIGS. 5A and 5B are partial perspective views of process modules that include a blocking shield according to various embodiments of the present disclosure.

FIGS. 6A and 6B are partial perspective views of process modules that include a blocking shield according to various embodiments of the present disclosure.

FIG. 7 is a block diagram illustrating a sputter deposition method according to various embodiments of the present disclosure.

### DETAILED DESCRIPTION

As discussed above, the present disclosure is directed to an apparatus and method for forming photovoltaic devices on a web substrate. In particular, the present disclosure relates to an apparatus and method for selectively depositing n-doped and/or transparent conductive layers so as to increase overall device uniformity. The web substrate typically has a width (i.e., a height of the web substrate for a vertically positioned web substrate, which is perpendicular to the length (i.e., movement direction) of the web substrate) of at least 10 cm, and oftentimes a width of about 1 meters or more, such as 1 to 5 meters. Deposition of a film with a uniform thickness and/or composition as a function of a large web substrate width is a challenge even in a large deposition chamber. Particularly, deposition rates of a target material may vary along the length of a target, which may lead to uneven layer formation. In one embodiment, without wishing to be bound by a particular theory, the present inventors determined that a lower deposition rates adjacent to end regions of a target may be compensated for by at least partially blocking indirect deposition from a central region of the target.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a direct physical contact between a surface of the first element and a surface of the second element.

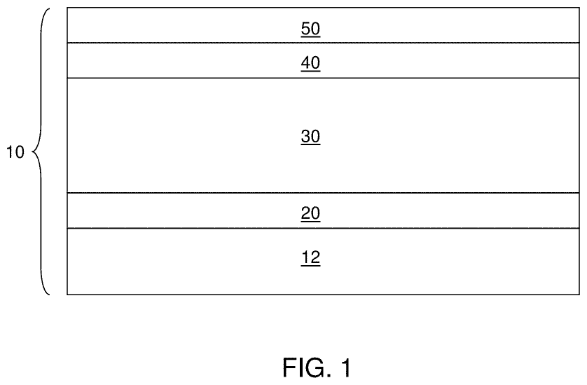

Referring to FIG. 1, a vertical cross-sectional view of a photovoltaic cell 10 is illustrated. The photovoltaic cell 10 includes a substrate, such as an electrically conductive substrate 12, a first electrode 20, a p-doped semiconductor layer 30, an n-doped semiconductor layer 40, a second electrode 50, and an optional antireflective (AR) coating layer (not shown).

The substrate 12 is preferably a flexible, electrically conductive material, such as a metallic foil that is fed into a system of one or more process modules as a web for deposition of additional layers thereupon. For example, the metallic foil of the conductive substrate 12 can be a sheet of a metal or a metallic alloy such as stainless steel, aluminum, or titanium. If the substrate 12 is electrically conductive, then it may comprise a part of the back side (i.e., first) electrode of the cell 10. Thus, the first (back side) electrode of the cell 10 may be designated as (20, 12). Alternatively, the conductive substrate 12 may be an electrically conductive or insulating polymer foil. Still alternatively, the substrate 12 may be a stack of a polymer foil and a metallic foil. In another embodiment, the substrate 12 may be a rigid glass substrate or a flexible glass substrate. The thickness of the substrate 12 can be in a range from 100 microns to 2 mm, although lesser and greater thicknesses can also be employed.

The first or back side electrode 20 may comprise any suitable electrically conductive layer or stack of layers. For example, electrode 20 may include a metal layer, which may be, for example, molybdenum. Alternatively, a stack of molybdenum and sodium and/or oxygen doped molybdenum layers may be used instead, as described in U.S. Pat. No. 8,134,069, which is incorporated herein by reference in its entirety. In another embodiment, the first electrode 20 can include a molybdenum material layer doped with K and/or Na, i.e., MoKₓ or Mo(Na,K)ₓ, in which x can be in a range from 1.0×10⁻⁶ to 1.0×10⁻². The electrode 20 can have a thickness in a range from 500 nm to 1 micron, although lesser and greater thicknesses can also be employed.

The p-doped semiconductor layer 30 can include a p-type sodium doped copper indium gallium selenide (CIGS), which functions as a semiconductor absorber layer. The thickness of the p-doped semiconductor layer 30 can be in a range from 1 microns to 5 microns, although lesser and greater thicknesses can also be employed.

The n-doped semiconductor layer 40 includes an n-doped semiconductor material such as CdS, ZnS, ZnSe, or an alternative metal sulfide or a metal selenide. The thickness of the n-doped semiconductor layer 40 is typically less than the thickness of the p-doped semiconductor layer 30, and can be in a range from 30 nm to 100 nm, although lesser and greater thicknesses can also be employed. The junction between the p-doped semiconductor layer 30 and the n-doped semiconductor layer 40 is a p-n junction. The n-doped semiconductor layer 40 can be a material which is substantially transparent to at least part of the solar radiation. The n-doped semiconductor layer 40 is also referred to as a window layer or a buffer layer.

The second (e.g., front side or top) electrode 50 comprises one or more transparent conductive layers 50. The transparent conductive layer 50 is conductive and substantially transparent. The transparent conductive layer 50 can include one or more transparent conductive materials, such as ZnO, indium tin oxide (ITO), Al doped ZnO (“AZO”), Boron doped ZnO (“BZO”), or a combination or stack of higher resistivity AZO and lower resistivity ZnO, ITO, AZO and/or BZO layers. The second electrode 50 contacts an electrically conductive part (e.g., a metal wire or trace) of an interconnect, such as an interconnect described in U.S. Pat. No. 8,912,429, issued Dec. 16, 2014, which is incorporated herein by reference in its entirety, or any other suitable interconnect that is used in photovoltaic panels.

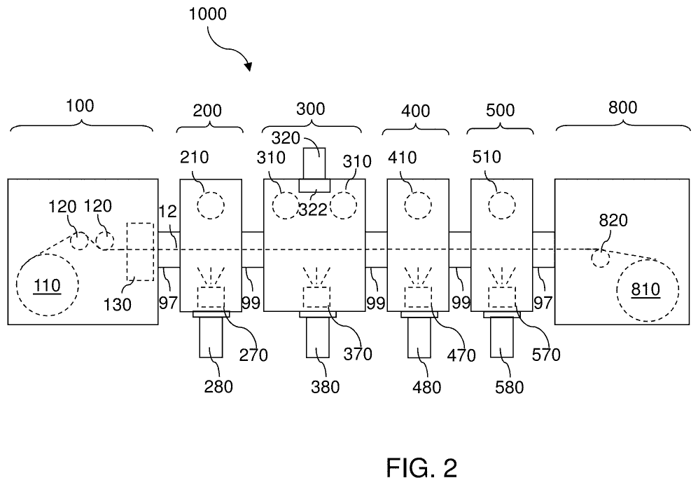

Referring now to FIG. 2, an apparatus 1000 for forming the photovoltaic cell 10 illustrated in FIG. 1 is shown. The apparatus 1000 is a first exemplary modular deposition apparatus that can be used to manufacture the photovoltaic cell illustrated in FIG. 1. The apparatus 1000 includes an input unit 100, a first process module 200, a second process module 300, a third process module 400, a fourth process module 500, and an output unit 800 that are sequentially connected to accommodate a continuous flow of the substrate 12 in the form of a web foil substrate layer through the apparatus. The modules (100, 200, 300, 400, 500) may comprise the modules described in U.S. Pat. No. 9,303,316, issued on Apr. 5, 2016, incorporated herein by reference in its entirety, or any other suitable modules. The first, second, third, and fourth process modules (200, 300, 400, 500) can be under vacuum by first, second, third, and fourth vacuum pumps (280, 380, 480, 580), respectively. The first, second, third, and fourth vacuum pumps (280, 380, 480, 580) can provide a suitable level of respective base pressure for each of the first, second, third, and fourth process modules (200, 300, 400, 500), which may be in a range from 1.0×10⁻⁹ Torr to 1.0×10⁻² Torr, and preferably in range from 1.0×10⁻⁹ Torr to 1.0×10⁻⁵ Torr.

Each neighboring pair of process modules (200, 300, 400, 500) is interconnected employing a vacuum connection unit 99, which can include a vacuum tube and an optional slit valve that enables isolation while the substrate 12 is not present. The input unit 100 can be connected to the first process module 200 employing a sealing connection unit 97. The last process module, such as the fourth process module 500, can be connected to the output unit 800 employing another sealing connection unit 97.

The substrate 12 can be a metallic or polymer web foil that is fed into a system of process modules (200, 300, 400, 500) as a web for deposition of material layers thereupon to form the photovoltaic cell 10. The substrate 12 can be fed from an entry side (i.e., at the input module 100), continuously move through the apparatus 1000 without stopping, and exit the apparatus 1000 at an exit side (i.e., at the output module 800). The substrate 12, in the form of a web, can be provided on an input spool 110 provided in the input module 100.

The substrate 12, as embodied as a metal or polymer web foil, is moved throughout the apparatus 1000 by input-side rollers 120, output-side rollers 820, and additional rollers (not shown) in the process modules (200, 300, 400, 500), vacuum connection units 99, or sealing connection units 97, or other devices. Additional guide rollers may be used. Some rollers (120, 820) may be bowed to spread the web (i.e., the substrate 12), some may move to provide web steering, some may provide web tension feedback to servo controllers, and others may be mere idlers to run the web in desired positions.

The input module 100 can be configured to allow continuous feeding of the substrate 12 by adjoining multiple foils by welding, stapling, or other suitable means. Rolls of substrates 12 can be provided on multiple input spools 110. A joinder device 130 can be provided to adjoin an end of each roll of the substrate 12 to a beginning of the next roll of the substrate 12. In one embodiment, the joinder device 130 can be a welder or a stapler. An accumulator device (not shown) may be employed to provide continuous feeding of the substrate 12 into the apparatus 1000 while the joinder device 130 adjoins two rolls of the substrate 12.

In one embodiment, the input module 100 may perform pre-processing steps. For example, a pre-clean process may be performed on the substrate 12 in the input module 100. In one embodiment, the substrate 12 may pass by a heater array (not shown) that is configured to provide at least enough heat to remove water adsorbed on the surface of the substrate 12. In one embodiment, the substrate 12 can pass over a roller configured as a cylindrical rotary magnetron. In this case, the front surface of substrate 12 can be continuously cleaned by DC, AC, or RF sputtering as the substrate 12 passes around the roller/magnetron. The sputtered material from the substrate 12 can be captured on a disposable shield. Optionally, another roller/magnetron may be employed to clean the back surface of the substrate 12. In one embodiment, the sputter cleaning of the front and/or back surface of the substrate 12 can be performed with linear ion guns instead of magnetrons. Alternatively or additionally, a cleaning process can be performed prior to loading the roll of the substrate 12 into the input module 100. In one embodiment, a corona glow discharge treatment may be performed in the input module 100 without introducing an electrical bias.

The output module 800 can include an output spool 810, which winds the web embodying the photovoltaic cell 10. The photovoltaic cell 10 is the combination of the substrate 12 and the deposited layers (20, 30, 40, 50) thereupon.

In one embodiment, the substrate 12 may be oriented in one direction in the input module 100 and/or in the output module 800, and in a different direction in the process modules (200, 300, 400, 500). For example, the substrate 12 can be oriented generally horizontally in the input module 100 and the output module 800, and generally vertically in the process module(s) (200, 300, 400, 500). A turning roller or turn bar (not shown) may be provided to change the orientation of the substrate 12, such as between the input module 100 and the first process module 200. In an illustrative example, the turning roller or the turn bar in the input module can be configured to turn the web substrate 12 from an initial horizontal orientation to a vertical orientation. Another turning roller or turn bar (not shown) may be provided to change the orientation of the substrate 12, such as between the last process module (such as the fourth process module 500) and the output module 800. In an illustrative example, the turning roller or the turn bar in the input module can be configured to turn the web substrate 12 from the vertical orientation employed during processing in the process modules (200, 300, 400, 500) to a horizontal orientation.

The input spool 110 and optional output spool 810 may be actively driven and controlled by feedback signals to keep the substrate 12 in constant tension throughout the apparatus 1000. In one embodiment, the input module 100 and the output module 800 can be maintained in the air ambient at all times while the process modules (200, 300, 400, 500) are maintained at vacuum during layer deposition.

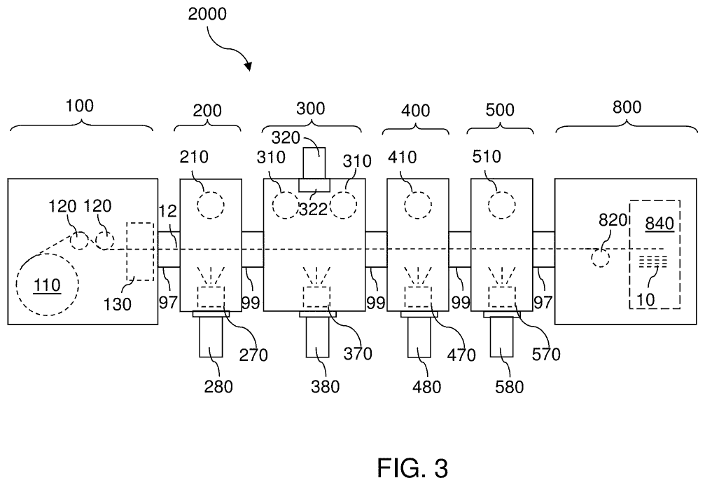

Referring to FIG. 3, a second exemplary modular deposition apparatus 2000 is illustrated, which can be used to manufacture the photovoltaic cell illustrated in FIG. 1. The second exemplary modular deposition apparatus 2000 includes an alternative output module 800, which includes a cutting apparatus 840 instead of an output spool 810. The web containing the photovoltaic cells 10 can be fed into the cutting apparatus 840 in the output module 800, and can be cut into discrete sheets of photovoltaic cells 10 instead of being rolled onto an output spool 810. The discrete sheets of photovoltaic cells are then interconnected using interconnects to form a photovoltaic panel (i.e., a solar module) which contains an electrical output.

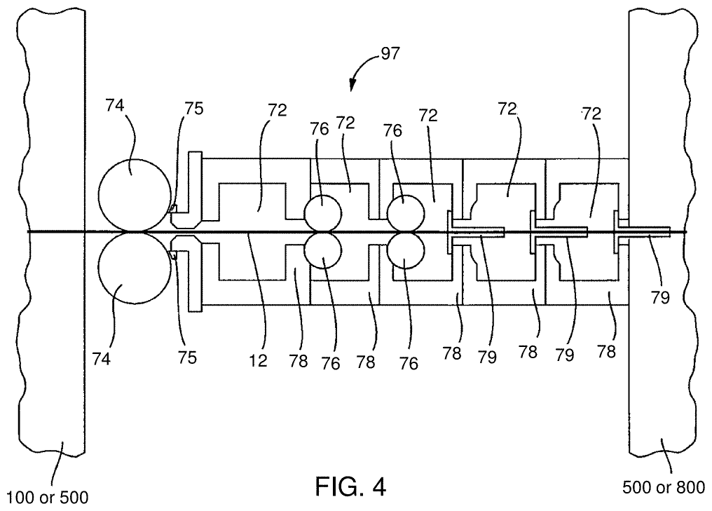

Referring to FIG. 4, an exemplary sealing connection unit 97 is illustrated. The unit 97 may comprise the sealing unit described in U.S. Pat. No. 9,303,316, issued on Apr. 5, 2016, incorporated herein by reference in its entirety, or any other suitable sealing unit. The sealing connection unit 97 is configured to allow the substrate 12 to pass out of a preceding unit (such as the input unit 100 or the last processing chamber such as the fourth process module 500) and into a subsequent unit (such as the first process module 200 or the output unit 800), while impeding the passage of gasses such as atmospheric gasses or processing gasses into or out of the units that the sealing connection unit 97 is adjoined to. The sealing connection unit 97 can include multiple isolation chambers 72.

The staged isolation chambers 72 can be configured to maintain internal pressures that graduate from atmospheric on a first side of the sealing connection unit 97 (such as the side of the input module 100 or the output module 800) to a high vacuum on the second side of the sealing connection unit 97 opposite of the first side (such as the side of the first process module 200 or the last process module 500). Multiple isolation chambers 72 can be employed to ensure that the pressure difference at any sealing surface is generally less than the pressure difference between atmospheric pressure and the high vacuum inside the process module.

The substrate 12 enters the sealing unit 97 between two external nip rollers 74. Each of the isolation chambers 72 of the sealing connection unit 97 can be separated by an internal divider 78, which is an internal wall among the isolation chambers 72. A pair of internal nip rollers 76, similar in function and arrangement to that of the external rollers 74, may be provided proximate to the internal dividers 78 between some of the neighboring internal chambers 72. The passage between the internal rollers 76 is generally closed off by rolling seals between the internal rollers 76 and the substrate 12. The internal dividers 78 may include curved sockets or contours that are configured to receive internal rollers 76 of a similar radius of curvature. The passage of gasses from one isolation chamber 72 to a neighboring, lower pressure internal chamber 72 may be reduced by a simple surface to surface contact between the internal roller 76 and the divider 78.

In other embodiments, a seal such as a wiper seal 75 may be provided for some or all of the internal rollers 76 to further reduce the infiltration of gasses into neighboring isolation chambers 72. The internal rollers 76 may be freely spinning rollers, or may be powered to control the rate of passage of the substrate 12 through the sealing connection unit 97. Between other chambers 72, the passage of gasses between neighboring chambers 72 may be limited by parallel plate conductance limiters 79. The parallel plate conductance limiters 79 are generally flat, parallel plates that are arranged parallel to the surface of the substrate 12 and are spaced apart a distance slightly larger than the thickness of the substrate 12. The parallel plate conductance limiters 79 allow the substrate to pass between the chambers 72 while limiting the passage of gasses between chambers 72.

In one embodiment, the sealing connection unit 97 may also include inert gas purge at the in-feed nip. In one embodiment, the sealing connection unit 97 may also include optional reverse crown or spreading rollers. The difference in pressure between neighboring chambers may deform the internal rollers 76, causing them to deflect or crown towards the chamber with a lower pressure. The reverse crown rollers are placed such that they correct for vacuum-induced deflection of the internal rollers 76. Thus, other than the slight deformation corrected by the reverse crown rollers, the sealing connection unit 97 is configured to pass the web substrate without bending or turning or scratching the web substrate 12.

Referring back to FIGS. 2 and 3, each of the first, second, third, and fourth process modules (200, 300, 400, 500) can deposit a respective material layer to form the photovoltaic cell 10 (shown in FIG. 1) as the substrate 12 passes through the first, second, third, and fourth process modules (200, 300, 400, 500) sequentially. The modules (100, 200, 300, 400, 500) may comprise first, second, third, and fourth heaters (270, 370, 470, 570) configured to heat the substrate 12 to a corresponding appropriate deposition temperature.

Optionally, one or more additional process modules (not shown) may be added between the input module 100 and the first process module 200 to sputter a back side protective layer on the back side of the substrate 12 before deposition of the first electrode 20 in the first process module 200. Further, one or more barrier layers may be sputtered over the front surface of the substrate 12 prior to deposition of the first electrode 20. Alternatively or additionally, one or more process modules (not shown) may be added between the first process module 200 and the second process module 300 to sputter one or more adhesion layers between the first electrode 20 and the p-doped semiconductor layer 30 including a chalcogen-containing compound semiconductor material.

The first process module 200 includes a first sputtering target 210, which includes the material of the first electrode 20 in the photovoltaic cell 10 illustrated in FIG. 1. The first heater 270 can be provided to heat the web substrate 12 to an optimal temperature for deposition of the first electrode 20. In one embodiment, a plurality of first sputtering targets 210 and a plurality of first heaters 270 may be employed in the first process module 200. In one embodiment, the at least one first sputtering target 210 can be mounted on dual cylindrical rotary magnetron(s), or planar magnetron(s) sputtering targets, or RF sputtering targets. In one embodiment, the at least one first sputtering target 210 can include a molybdenum target, a molybdenum-sodium, and/or a molybdenum-sodium-oxygen target, as described in U.S. Pat. No. 8,134,069, incorporated herein by reference in its entirety.

The portion of the substrate 12 on which the first electrode 20 is deposited is moved into the second process module 300. A p-doped chalcogen-containing compound semiconductor material is deposited to form the p-doped semiconductor layer 30, such as a sodium doped CIGS absorber layer. In one embodiment, the p-doped chalcogen-containing compound semiconductor material can be deposited employing reactive alternating current (AC) magnetron sputtering in a sputtering atmosphere that includes argon and a chalcogen-containing gas at a reduce pressure. In one embodiment, multiple metallic component targets 310 including the metallic components of the p-doped chalcogen-containing compound semiconductor material can be provided in the second process module 300.

As used herein, the “metallic components” of a chalcogen-containing compound semiconductor material refers to the non-chalcogenide components of the chalcogen-containing compound semiconductor material. For example, in a copper indium gallium selenide (CIGS) material, the metallic components include copper, indium, and gallium. The metallic component targets 310 can include an alloy of all non-metallic materials in the chalcogen-containing compound semiconductor material to be deposited. For example, if the chalcogen-containing compound semiconductor material is a CIGS material, the metallic component targets 310 can include an alloy of copper, indium, and gallium. More than two targets 310 may be used. The second heater 370 can be a radiation heater that maintains the temperature of the web substrate 12 at the deposition temperature, which can be in a range from 400° C. to 800° C., such as a range from 500° C. to 700° C., which is preferable for CIGS deposition.

At least one chalcogen-containing gas source 320 (such as a selenium evaporator) and at least one gas distribution manifold 322 can be provided on the second process module 300 to provide a chalcogen-containing gas into the second process module 300. While FIGS. 2 and 3 schematically illustrate a second process module 300 including two metallic component targets 310, a single chalcogen-containing gas source 320, and a single gas distribution manifold 322, multiple instances of the chalcogen-containing gas source 320 and/or the gas distribution manifold 322 can be provided in the second process module 300.

The chalcogen-containing gas provides chalcogen atoms that are incorporated into the deposited chalcogen-containing compound semiconductor material. For example, if a CIGS material is to be deposited for the p-doped semiconductor layer 30, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be a selenium evaporator, such as an effusion cell that can be heated to generate selenium vapor.

The chalcogen incorporation during deposition of the chalcogen-containing compound semiconductor material determines the properties and quality of the chalcogen-containing compound semiconductor material in the p-doped semiconductor layer 30. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the chalcogen-containing compound semiconductor material. The p-type doping in the p-doped semiconductor layer 30 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets 310.

In one embodiment, each metallic component target 310 can be employed with a respective magnetron (not expressly shown) to deposit a chalcogen-containing compound semiconductor material with a respective composition. In one embodiment, the composition of the metallic component targets 310 can be gradually changed along the path of the substrate 12 so that a graded chalcogen-containing compound semiconductor material can be deposited in the second process module 300. For example, if a CIGS material is deposited as the chalcogen-containing compound semiconductor material of the p-doped semiconductor layer 30, the atomic percentage of gallium of the deposited CIGS material can increase as the substrate 12 progresses through the second process module 300. In this case, the p-doped CIGS material in the p-doped semiconductor layer 30 of the photovoltaic cell 10 can be graded such that the band gap of the p-doped CIGS material increases with distance from the interface between the first electrode 20 and the p-doped semiconductor layer 30.

In one embodiment, the total number of metallic component targets 310 may be in a range from 3 to 20. In an illustrative example, the composition of the deposited chalcogen-containing compound semiconductor material (e.g., the p-doped CIGS material absorber 30) can be graded such that the band gap of the p-doped CIGS material varies (e.g., increases or decreases gradually or in steps) with distance from the interface between the first electrode 20 and the p-doped semiconductor layer 30. For example, the band gap can be about 1 eV at the interface with the first electrode 20, and can be about 1.3 eV at the interface with subsequently formed n-doped semiconductor layer 40.

The second process module 300 includes a deposition system for deposition of a chalcogen-containing compound semiconductor material for forming the p-doped semiconductor layer 30. As discussed above, the deposition system includes a vacuum enclosure attached to a vacuum pump (such as at least one second vacuum pump 380), and a sputtering system comprising at least one sputtering target (such as the at least one metallic component target 310, for example a Cu—In—Ga target) located in the vacuum enclosure and at least one respective magnetron. The sputtering system is configured to deposit a material including at least one component of a chalcogen-containing compound semiconductor material (i.e., the non-chalcogen metallic component(s) of the chalcogen-containing compound semiconductor material) over the substrate 12 in the vacuum enclosure. In other words, the module 300 is a reactive sputtering module in which the chalcogen gas (e.g., selenium vapor) from gas distribution manifolds 322 reacts with the metal (e.g., Cu—In—Ga) sputtered from the targets 310 to form the chalcogen-containing compound semiconductor material (e.g., CIGS) layer 30 over the substrate 12.

In an illustrative example, the chalcogen-containing compound semiconductor material can comprise a copper indium gallium selenide, and the at least one sputtering target (i.e., the metallic component targets 310) can comprise materials selected from copper, indium, gallium, and alloys thereof (e.g., Cu—In—Ga alloy, CIG). In one embodiment, the chalcogen-containing gas source 320 can be configured to supply a chalcogen-containing gas selected from gas phase selenium and hydrogen selenide (H₂Se). In one embodiment, the chalcogen-containing gas can be gas phase selenium, i.e., vapor phase selenium, which is evaporated from a solid source in an effusion cell.

While the present disclosure is described employing an embodiment in which metallic component targets 310 are employed in the second process module 300, embodiments are expressly contemplated herein in which each, or a subset, of the metallic component targets 310 is replaced with a pair of two sputtering targets (such as a copper target and an indium-gallium alloy target), or with a set of three supper targets (such as a copper target, an indium target, and a gallium target).

Generally speaking, the chalcogen-containing compound semiconductor material can be deposited by providing a substrate 12 in a vacuum enclosure attached to a vacuum pump 380, providing a sputtering system comprising at least one sputtering target 310 located in the vacuum enclosure and at least one respective magnetron located inside a cylindrical target 310 or behind a planar target (not explicitly shown), and providing a gas distribution manifold 322 having a supply side and a distribution side. The chalcogen-containing compound semiconductor can be deposited by sputtering a material including at least one component (i.e., the non-chalcogen component) of a chalcogen-containing compound semiconductor material onto the substrate 12, while flowing a chalcogen-containing gas (e.g., Se vapor) into the vacuum chamber through the gas distribution manifold 322.

The portion of the substrate 12 on which the first electrode 20 and the p-doped semiconductor layer 30 are deposited is subsequently passed into the third process module 400. An n-doped semiconductor material is deposited in the third process module 400 to form the n-doped semiconductor layer 40 illustrated in the photovoltaic cell 10 of FIG. 1. The third process module 400 can include, for example, a third sputtering target 410 (e.g., a CdS target) and a magnetron (not expressly shown). The third sputtering target 410 can include, for example, a rotating AC magnetron, an RF magnetron, or a planar magnetron.

The portion of the substrate 12 on which the first electrode 20, the p-doped semiconductor layer 30, and the n-doped semiconductor layer 40 are deposited is subsequently passed into the fourth process module 500. A transparent conductive oxide material is deposited in the fourth process module 500 to form the second electrode comprising a transparent conductive layer 50 illustrated in the photovoltaic cell 10 of FIG. 1. The fourth process module 500 can include, for example, a fourth sputtering target 510 and a magnetron (not expressly shown). The fourth sputtering target 510 can include, for example, a ZnO, AZO or ITO target and a rotating AC magnetron, an RF magnetron, or a planar magnetron. A transparent conductive oxide layer 50 is deposited over the material stack (30, 40) including the p-n junction. In one embodiment, the transparent conductive oxide layer 50 can comprise a material selected from tin-doped indium oxide, aluminum-doped zinc oxide, and zinc oxide. In one embodiment, the transparent conductive oxide layer 50 can have a thickness in a range from 60 nm to 1,800 nm.

Subsequently, the web substrate 12 passes into the output module 800. The substrate 12 can be wound onto the output spool 810 (which may be a take up spool) as illustrated in FIG. 2, or can be sliced into photovoltaic cells using a cutting apparatus 840 as illustrated in FIG. 3.

### Deposition Control

The deposition profile of a target may vary across a substrate. For example, edge regions of a sputtering target may generate less sputtered target material than a central region thereof. Accordingly, edge regions of a substrate may experience lower deposition rates than a central region thereof. Such deposition variation may result in layer and/or device thickness variations, which may lead to adverse effects in a finished thin-film device, such as a photovoltaic cell. For example, thickness variations may result in color variations and/or performance reductions in photovoltaic devices.

Conventional methods of decreasing such thickness variations may include employing a shield disposed directly between a target and a substrate in an effort to block deposition onto a central region of a target and thereby relatively increase deposition at edge regions of the substrate. However, in order to achieve a uniform deposition profile, such deposition methods may require the use of multiple blocked targets and multiple unblocked targets that are operated at high power to maintain a desired layer thickness. As a result, such systems may experience temperature spikes, which may degrade sensitive sputtered materials such as transparent metal oxide layers. In addition, operating sputtering targets at high power levels may also result in cracking and/or de-bonding of target material from underlying ceramic materials, thereby reducing target lifetimes.

In addition, a substantial amount of costly target material may be lost due to be deposited on target shields, resulting in increased costs. Further, the accumulation of sputtered target material on blocking shields may result in target material flaking, which may result in electrical arcing and/or shorting of targets.

In view of the above and/or other drawbacks of conventional deposition systems, various embodiments of the present disclosure provide deposition systems that provide improved deposition uniformity by controlling indirect target material deposition. For example, during a physical vapor deposition process such as sputtering, sputtered target material may be deposited onto a deposition substrate directly and/or indirectly.

Accordingly, the term “direct deposition” may refer to a process by which atoms of a target material are ejected from a target (e.g., sputtered) and travel along a substantially straight line normal or substantially normal (e.g., within 1 to 20 degrees of normal) to the substrate surface before being deposited on a deposition substrate. In contrast, the term “indirect deposition” may refer to a process by which atoms of a target material are ejected from a target along a straight line that is not normal or substantially normal to the substrate surface (e.g., in a diagonal line having an incidence angle on the substrate of more less than 70 degrees), or by which atoms of the target material are ejected from the target do not extend from the target to a deposition substrate along a straight line such that the atoms must change direction one or more times before being deposited on the substrate.

In order to provide improved deposition control, various embodiments may include one or more process modules having peripherally shielded sputtering targets. As used herein, the term a “peripherally shielded” target may refer to a target disposed adjacent to one or more shields configured to at least partially block indirect deposition of a sputtered target material onto a substrate while permitting substantially all direct deposition of the sputtered target material from the target directly onto the substrate. For example, a peripheral shield of a peripherally shielded target may block all or substantially all indirect deposition onto certain regions of a substrate while permitting direct deposition.

In some embodiments, all targets included in a process module may be peripherally shielded. However, in some embodiments, a single process module may include peripherally shielded and unshielded targets, or separate modules including peripherally shielded and unshielded targets may be used.

For example, the fourth process module 500 of FIG. 2 may include one or more peripherally shielded targets configured to uniformly deposit a corresponding layer or film on the substrate 12. However, in some embodiments, peripheral shields may be used during the formation of any layer of a photovoltaic device. In particular, peripherally shielded deposition may be utilized to form any layer after the absorber layer 30 is formed on the substrate 12, as shown in FIG. 1.

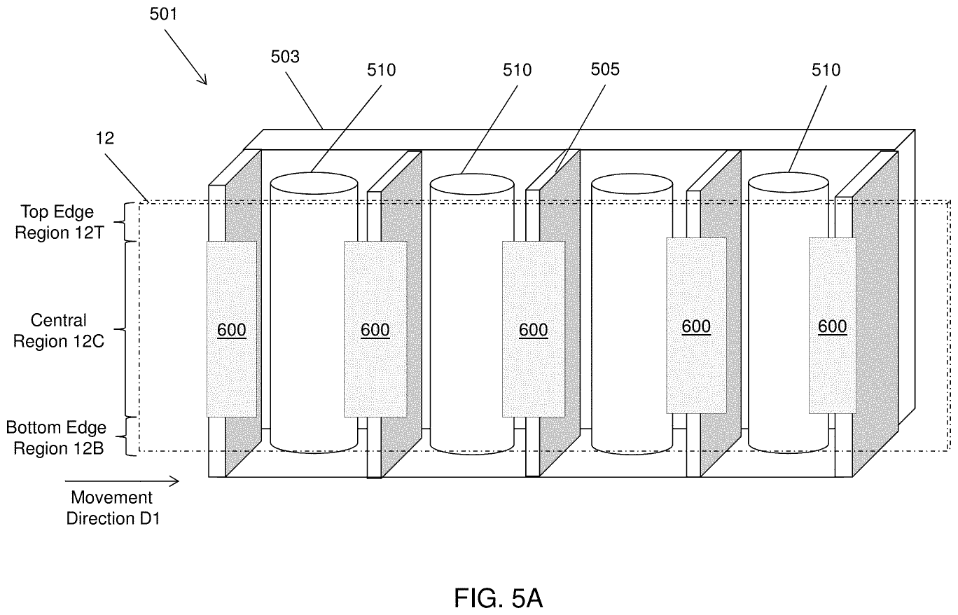

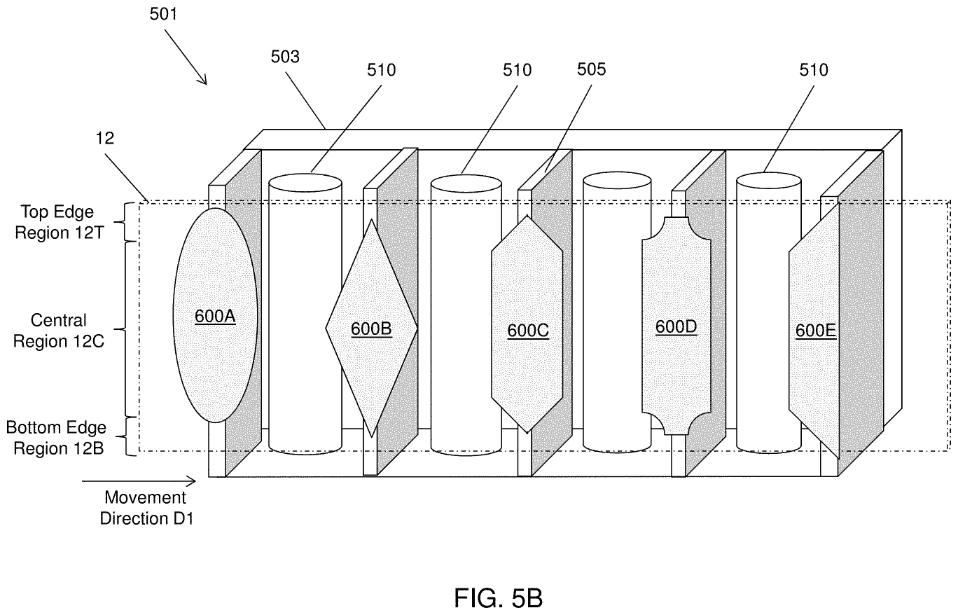

FIG. 5A is a partial perspective view of a process module 501 that includes a peripheral shield including a number of individual shields 600 (e.g., shield members) according to various embodiments of the present disclosure. FIG. 5B is a partial perspective view showing exemplary shield members that may alternatively be included in the process module 501 according to various embodiments of the present disclosure. The process module 501 may be similar to process modules 400 and/or 500, for example. Accordingly, only differences therebetween will be discussed in detail.

Referring to FIG. 5A, the process module 501 may include a number of sputtering targets 510 disposed in a vacuum enclosure 503. The vacuum enclosure 503 may include a number of partition walls 505 configured to separate the targets 510 and/or divide the vacuum enclosure 503 into separate chambers. However, in some embodiments, multiple targets may be disposed in a single chamber or enclosure. The targets 510 may include the same target material. For example, the targets 510 may include transparent conductive oxides, such as ZnO and/or Al-doped ZnO, or the like. However, in other embodiments, different target materials may be used.

The process module 501 may include a peripheral shield comprising a number of individual shield members 600. The shield members 600 may be attached to the partition walls 505. In other embodiments, the shield members 600 may be attached to a door of the vacuum enclosure 503, hung therein, or may be secured by any other suitable method or structure. The shield members 600 may be configured to peripherally shield each target 510. However, in some embodiments, one or more of the shield members 600 may be omitted such that one or more targets 510 are unshielded.

The shield members 600 may be formed of a conductive material, such as a metal. In some embodiments, the shield members 600 may be electrically floated or grounded, or may have an applied electrical bias that is opposite to an electrical bias applied to the targets 510. For example, when electrically biased, the shield members 600 may operate as anodes during sputtering of the targets 510, with a magnetron included in each of the targets 510 operating as a cathode.

The shield members 600 may be disposed such that a substrate 12 moving through the process module in a movement direction D1 is directly exposed to the targets 510. In other words, the shield members 600 may be disposed in an interstitial position between adjacent targets 510, or may be laterally disposed with respect to a single target 510 and a line directly between the target 510 and the substrate 12. Accordingly, the shield members 600 may be configured to block the indirect deposition of sputtered target material, while allowing for the direct deposition of sputtered target material (e.g., target material that moves directly from a target 510 to the substrate 12).

The shield members 600 may have the same shape, such as the rectangular shield members 600 shown in FIG. 5A. However, in some embodiments, or one or more of the shields 600 may have a different shape. In particular, in some embodiments the shape of one or more shield members may be modified to control target material deposition onto the substrate 12. For example, the shield members 600 may be configured to provide higher deposition rates at edge regions of the substrate 12, such as top and bottom edge regions 12T, 12B, as compared to a central region 12C of the substrate 12. In particular, the shield members 600 may be configured to block all or substantially all (e.g., at least 95%) of indirect deposition onto the central region 12C of the substrate 12.

For example, as shown in FIG. 5B, the process module 501 may include a peripheral shield comprising one or more oval-shaped shield members 600A, diamond-shaped shield members 600B, pentagonal shield members 600C, rounded corner rectangular shield members 600C, trapezoidal shield members 600E, combinations thereof, or the like. However, the present disclosure is not limited to any particular shield member shape, and the shield members may be modified to provide different deposition patterns. For example, an hourglass-shaped shield member may be utilized to provide relatively higher deposition rates at the central region 12C than at the top and bottom regions 12T, 12B of the substrate 12, in some embodiments. Accordingly, a peripheral shield may include shield members configured to improve layer deposition rate control. For example, a peripheral shield may be configured to increase deposition rate uniformity across a substrate and/or overall device thickness uniformity.

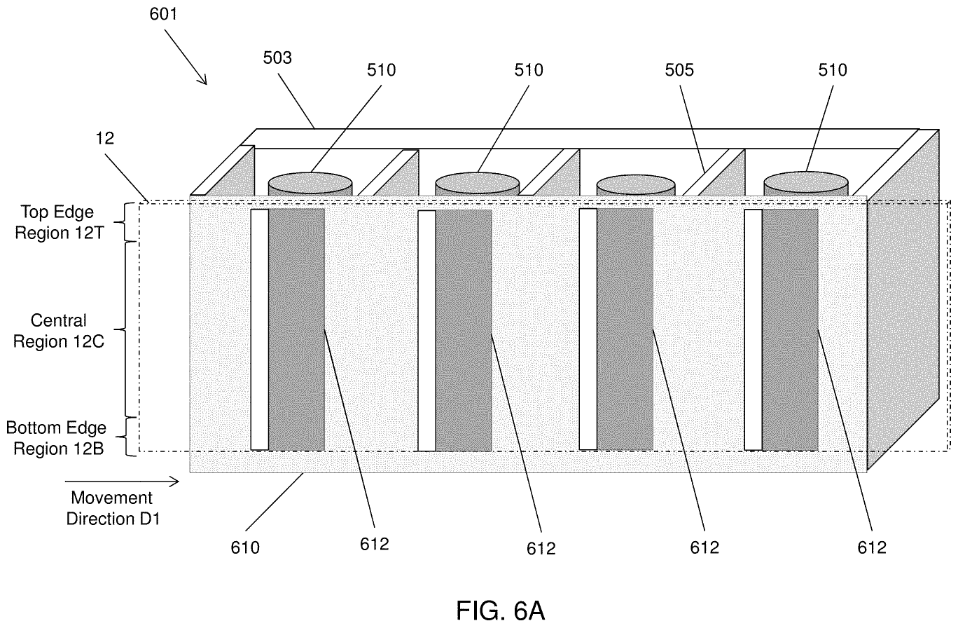

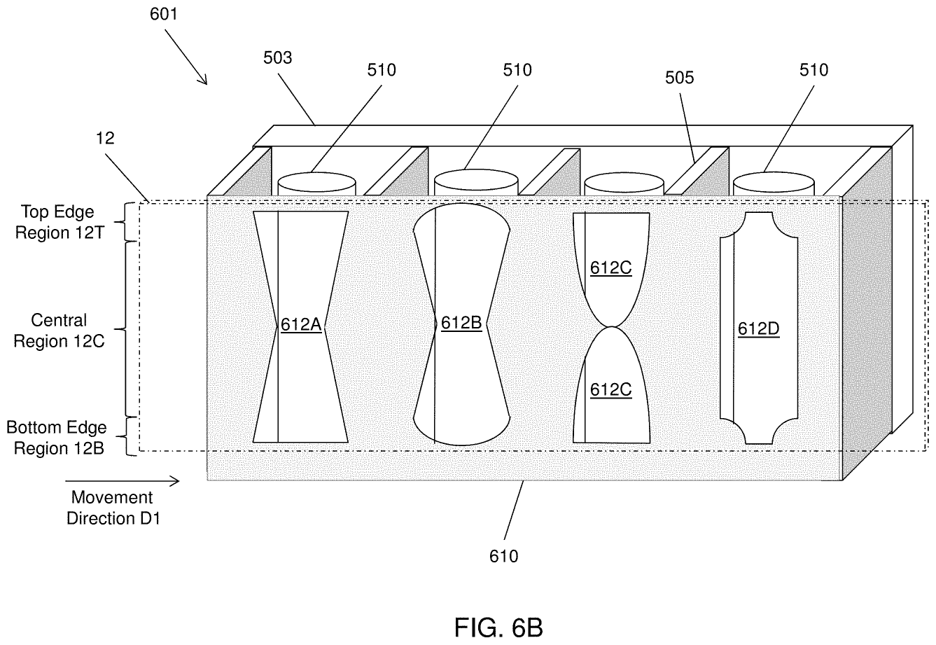

FIG. 6A is a partial perspective view of process module 601 that includes a peripheral shield 610 including deposition apertures 612 according to various embodiments of the present disclosure. FIG. 6B is a partial perspective view showing exemplary apertures that may alternatively be included in the peripheral shield 610 of process module 601 according to various embodiments of the present disclosure. The process module 601 may be similar to process module 501. Accordingly, only differences therebetween will be discussed in detail.

Referring to FIG. 6A, the process module 601 may include a number of sputtering targets 510 disposed in a vacuum enclosure 503. The vacuum enclosure 503 may include a number of partition walls 505 configured to separate the targets 510 and/or divide the vacuum enclosure 503 into separate chambers. However, in some embodiments, multiple targets 510 may be disposed in a single chamber or enclosure. The targets 510 may include the same target material. For example, the targets 510 may include transparent conductive oxides, such as ZnO and/or Al-doped ZnO, or the like. However, in other embodiments, different target materials may be used.

The peripheral shield 610 may be disposed between the vacuum chamber 503 and a substrate 12. For example, the peripheral shield 610 may be disposed between the substrate 12 and an interstitial space located between adjacent targets 510. The shield 610 may be attached to the partition walls 505. In other embodiments, the shield 610 may be attached to a door of the vacuum enclosure 503, hung therein, or may be secured by any other suitable method or structure. The peripheral shield 610 may be disposed in front of each or the targets 510 as shown in FIG. 6A. In other embodiments the peripheral shield 610 may be configured such that one or more of the targets 510 is unshielded.

The peripheral shield 610 may be formed of a conductive material, such as a metal. In some embodiments, the peripheral shield 610 may be electrically grounded or floated, or may have an applied electrical bias that is opposite to an electrical bias applied to the targets 510. For example, when electrically biased, the peripheral shield 610 may operate as an anode during sputtering of the targets 510, with a magnetron included in each of the targets 510 operating as a cathode.

The peripheral shield 610 may comprise deposition apertures 612 configured to directly expose the targets 510 to the substrate 12. For example, target material ejected from each target 510 can move in a substantially straight line to reach the substrate 12 by passing through a corresponding aperture 612. Accordingly, the shield 610 may be configured such that as the substrate 12 moves through the process module 601 in a movement direction D1, portions of the substrate 12 are directly exposed to the targets 510 such that direct deposition of sputtered target material may occur. In other words, the shield 600 may be configured to cover interstitial positions between adjacent targets 510 and may be laterally disposed with respect to a single target 510 and a line directly between the target 510 and the substrate 12. Accordingly, the peripheral shield 610 may be configured to block at least some indirect deposition of sputtered target material, while allowing for the all or substantially all direct deposition of sputtered target material.

The apertures 612 may have any suitable shape. For example, the apertures 612 may all be rectangular as shown in FIG. 5A. However, in some embodiments, or one or more of the apertures 612 may have different shapes. In particular, in some embodiments the shape of one or more apertures 612 may be modified to provide a desired deposition profile on the substrate 12. In some embodiments, the apertures 612 may be configured to provide higher deposition rates at edge regions of the substrate 12, such as top and bottom edge regions 12T, 12B, as compared to a central region 12C of the substrate 12.

For example, as shown in FIG. 5B, the process module 601 may include a peripheral shield 610 having one or more hour glass apertures 612A, rounded hourglass apertures 612B, parabolic apertures 612C, rounded corner rectangular apertures 612D, combinations thereof, or the like. However, the present disclosure is not limited to any particular aperture shape, and the apertures may be modified to provide different deposition patterns. For example, apertures such as apertures 612A, 612B, and 612C may be utilized to provide relatively lower deposition rates at the central region 12C than at the top and bottom regions 12T, 12B of the substrate 12, while apertures such as aperture 612C may be utilized to provide relatively higher deposition rates at the central region 12C than at the top and bottom regions 12T, 12B of the substrate 12. Accordingly, the apertures 612 may be configured to improve layer and/or overall device thickness uniformity.

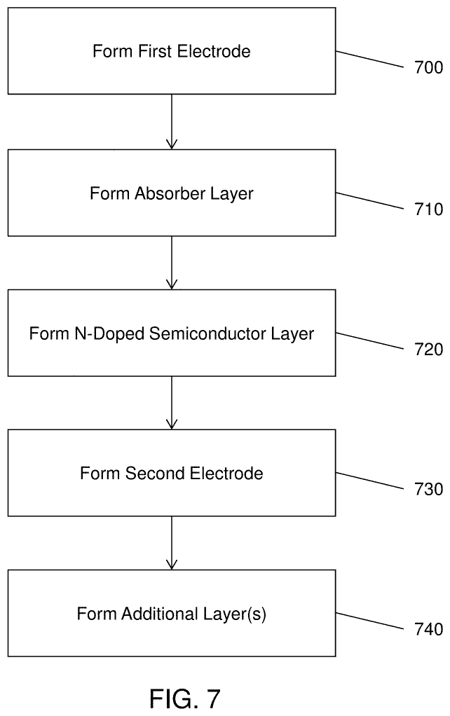

FIG. 7 is a block diagram illustrating a sputter deposition method according to various embodiments of the present disclosure. The method may involve using a deposition system as discussed above with regard to FIGS. 2 and 3, with the deposition system including at least one process module including peripherally shielded targets as discussed above with regard to FIGS. 5A, 5B, 6A, and 6B.

Referring to FIGS. 2, 3, 5A-5E, and 7, in step 700, the method may include forming a first or back side electrode on a substrate. For example, the first electrode may be deposited on the substrate while the substrate moves through the first process module 200.

In step 710, an absorber layer (i.e., p-doped semiconductor layer) may be formed on the first electrode. For example, the absorber layer may be deposited on the substrate while the substrate moves through the second process module 300.

In step 720, an n-doped semiconductor layer may be formed on the absorber layer. For example, the n-doped semiconductor layer may be deposited on the substrate while the substrate moves through the third process module 400.

In step 730, a second electrode may be formed on an n-doped semiconductor layer. For example, the second electrode may be deposited on the substrate while the substrate moves through the fourth process module 500.

Steps 720 and/or 730 may include using process modules including peripherally shielded targets as described above. For example, the second electrode may be formed by using peripherally shielded targets to selectively form target material layers on the substrate such that the material layers have improved uniformity. In particular, the peripherally shielded targets may be used to reduce film thickness variations that may otherwise occur due to deposition rate variations produced by unshielded targets by selectively blocking indirect deposition onto a central region of the substrate.

The method may optionally include step 740 in which additional layers may be formed on the substrate. For example, optional step 740 may include forming an anti-reflection layer and/or a protective layer on the substrate.

According to various embodiments of the present disclosure, provided are tunable systems and methods, including peripherally shielded deposition targets that may be configured to provide increased layer deposition uniformity during fabrication of a thin film device, such as a photovoltaic device, as compared to layers formed using unshielded targets. In particular, the present disclosure provides deposition modules having peripherally shielded targets that provide highly uniform layer deposition without suffering from reduced target deposition rates that may occur when using a blocking shield to directly block a target. Further, as compared to conventionally blocked target systems, the present peripherally shielded targets may be operated at a lower voltage, thereby reducing the risk of target de-bonding and/or fracture, and extending target lifetime.

In addition, various embodiments provide peripheral shields that experience reduced target material deposition, as compared to conventional blocking shields. Accordingly, various embodiments provide a lower risk of electrical arcing and/or short circuiting.

While sputtering was described as the preferred method for depositing all layers onto the substrate, some layers may be deposited by MBE, CVD, evaporation, plating, etc.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the present invention.

What is claimed is:

1. A sputter deposition system comprising a process module comprising:
a vacuum enclosure configured to receive a moving substrate;
sputtering targets disposed in the vacuum enclosure, each sputtering target comprising a target material; and
a peripheral shield disposed between the substrate and an interstitial space located between adjacent sputtering targets, the peripheral shield configured to at least partially block indirect deposition of sputtered target material onto the substrate and to permit direct deposition of the sputtered target material onto the substrate.

2. The deposition system of claim 1, wherein the peripheral shield comprises apertures, each aperture configured to directly expose a portion of the substrate to a corresponding sputtering target.

3. The deposition system of claim 2, wherein at least one of the apertures is configured so that opposing first and second edge regions of the substrate are exposed to a higher amount of indirect deposition than a central region of the substrate.

4. The deposition system of claim 2, wherein at least one of the apertures is configured such that the peripheral shield exposes opposing first and second edge regions of the substrate to indirect deposition of sputtered target material from at least one of the sputtering targets, and blocks substantially all indirect deposition of the sputtered target material onto a central region of the substrate.

5. The deposition system of claim 2, wherein:
a rate of direct deposition from each sputtering target is highest at a central region of the sputtering target and lowest at opposing edge regions of the sputtering target; and
the peripheral shield is configured to partially block the indirect deposition, such that a rate of the indirect deposition is highest at opposing edge regions of the substrate and lowest at a central region of the substrate.

6. The deposition system of claim 1, wherein the peripheral shield is electrically grounded or electrically floated such that a polarity of the peripheral shield is different from a polarity of magnetrons included in the sputtering targets.

7. The deposition system of claim 1, wherein the peripheral shield comprises individual shield members configured to at least partially block indirect deposition of the sputtered target material.

8. The deposition system of claim 7, wherein the shield members are configured to block relatively more of the sputtered target material from being indirectly deposited on a central region of the substrate, and to block relatively less of the sputtered target material from being indirectly deposited on opposing edge regions of the substrate.

9. The deposition system of claim 7, wherein each shield member is disposed between the substrate and an interstitial space located between adjacent targets.

10. The deposition system of claim 1, wherein the targets comprise the same type of target material.

11. The deposition system of claim 10, wherein the target material comprises a transparent conductive oxide.

12. The deposition system of claim 11, wherein the transparent conductive oxide comprises indium tin oxide, zinc oxide, or a doped zinc oxide.

13. The deposition system of claim 1, wherein the vacuum enclosure comprises partition walls separating the targets from one another.

14. The deposition system of claim 1, further comprising:
at least one spool or roller configured to continuously move the substrate in a vertical orientation along a first direction from an input port on the vacuum enclosure to an output port on the vacuum enclosure; and
additional process modules configured to deposit material vapors onto the substrate.

15. A sputter deposition method, comprising:
sputtering a target material using sputtering targets disposed in a vacuum enclosure; and
depositing, via direct deposition, the sputtered target material onto a substrate moving through the vacuum enclosure, while at least partially blocking indirect deposition of the sputtered target material onto the substrate using a peripheral shield disposed between the substrate and an interstitial space located between adjacent sputtering targets.

16. The method of claim 15, wherein:
a rate of direct deposition from each sputtering target is highest at a central region of the sputtering target and lowest at opposing edge regions of the sputtering target; and
the peripheral shield is configured to partially block indirect deposition such that a rate of indirect deposition is highest at opposing edge regions of the substrate and lowest at a central region of the substrate.

17. The method of claim 15, wherein the peripheral shield comprises apertures, each aperture configured to directly expose a portion of the substrate to a corresponding sputtering target.

18. The method of claim 15, wherein the peripheral shield comprises individual shield members configured to at least partially block indirect deposition of the sputtered target material.

19. The method of claim 15, wherein depositing, via direct deposition, the sputtered target material onto a substrate moving through the vacuum enclosure, while at least partially blocking indirect deposition of the sputtered target material onto the substrate using a peripheral shield disposed between the substrate and an interstitial space located between adjacent sputtering targets, comprises partially blocking indirect deposition of the sputtered target material, such that a deposition rate of the target material on the substrate is substantially constant in a direction perpendicular to a movement direction of the substrate.

20. The method of claim 15, wherein depositing, via direct deposition, the sputtered target material onto a substrate moving through the vacuum enclosure while at least partially blocking indirect deposition of the sputtered target material onto the substrate using a peripheral shield disposed between the substrate and an interstitial space located between adjacent sputtering targets comprises at least one of:
forming a first electrode on the substrate;
forming an absorber layer on the first electrode;
forming an n-doped semiconductor layer on the absorber layer; and
forming a second electrode on the n-doped semiconductor layer.
